(19) United States
(12) Patent Application Publication
(10) Pub. No.: US 2026/0090310 A1
(43) Pub. Date: Mar. 26, 2026

(54) SUBSTRATE PROCESSING DEVICE AND CONTROL METHOD

(71) Applicant: Tokyo Electron Limited, Tokyo (JP)

(72) Inventor: Tsutomu HIROKI, Yamanashi (JP)

(21) Appl. No.: 19/327,198

(22) Filed: Sep. 12, 2025

(30) Foreign Application Priority Data
Sep. 26, 2024 (JP) 2024-167173

(51) Int. Cl. H01L 21/67

(52) U.S. Cl. CPC H10P 72/0402

(57) ABSTRACT

A substrate processing device includes: a processing container; a stage configured to support a substrate in the processing container; an upper member that is positioned to face the stage so as to form a processing space therebetween; a gap adjusting part configured to adjust a width of a gap between the stage and the upper member; and a flow rectifying member that is positioned to surround the processing space, and the flow rectifying member has an opening through which at least a portion of gas flowing out from the processing space passes.

### CROSS-REFERENCE TO RELATED APPLICATIONS

This application is based on and claims priority to Japanese Patent Application No. 2024-167173, filed on Sep. 26, 2024, the entire content of which is incorporated herein by reference.

### BACKGROUND

### 1. Field of the Invention

The present disclosure relates to a substrate processing device and a method of controlling the substrate processing device.

### 2. Description of the Related Art

When there is a space between a processing space and an exhaust opening, the conductance of the space can be controlled using existing techniques.

### RELATED-ART DOCUMENT

### Patent Documents

Patent Document 1: Unexamined Japanese Patent Application Publication No. 2023-183485
Patent Document 2: Unexamined Japanese Patent Application Publication No. 2023-34298
Patent Document 3: U.S. Pat. No. 6,190,732

### SUMMARY OF THE INVENTION

An example of the present disclosure provides a substrate processing device. The substrate processing device includes: a processing container; a stage configured to support a substrate in the processing container; an upper member that is positioned to face the stage so as to form a processing space therebetween; a gap adjusting part configured to adjust a width of a gap between the stage and the upper member; and a flow rectifying member that is positioned to surround the processing space, and the flow rectifying member has an opening through which at least a portion of gas flowing out from the processing space passes.

### BRIEF DESCRIPTION OF THE DRAWINGS

FIG. 1 is a cross-sectional view showing a substrate processing device according to an embodiment of the present disclosure;

FIG. 2 is a perspective view showing an example of a flow rectifying member;

FIG. 3 is a first diagram for explaining a method of controlling the substrate processing device according to an embodiment of the present disclosure;

FIG. 4 is a second diagram for explaining the method of controlling the substrate processing device according to an embodiment of the present disclosure;

FIG. 5 is a third diagram for explaining the method of controlling the substrate processing device according to an embodiment of the present disclosure; and

FIG. 6 is a fourth diagram for explaining the method of controlling the substrate processing device according to an embodiment of the present disclosure.

### DESCRIPTION OF THE PREFERRED EMBODIMENTS

The present disclosure provides a technique for improving the uniformity in substrate processing.

According to the present disclosure, the uniformity in substrate processing can be improved.

A non-limiting example embodiment of the present disclosure will be described below with reference to the accompanying drawings. The same or substantially the same reference numerals will be assigned to the same or substantially the same members or components throughout the accompanying drawings, so that redundant description will be omitted in the following description.

### (Substrate Processing Device)

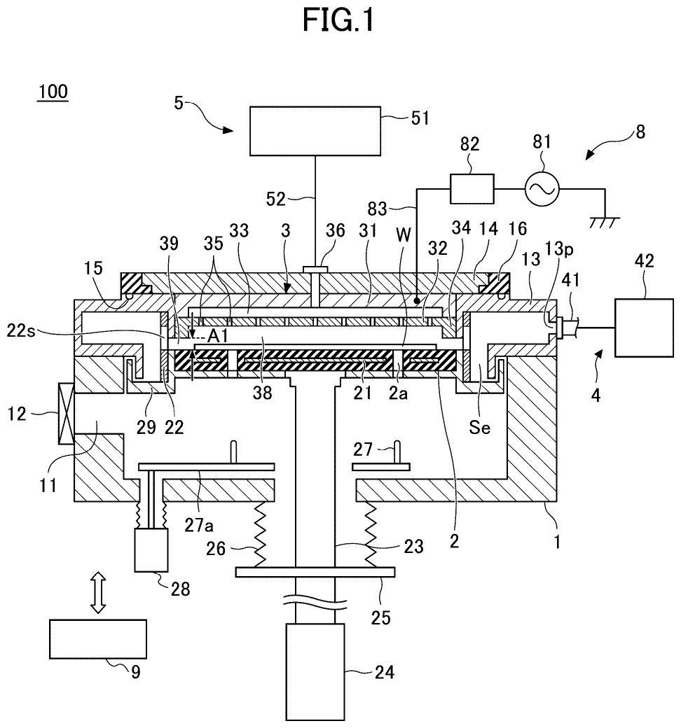

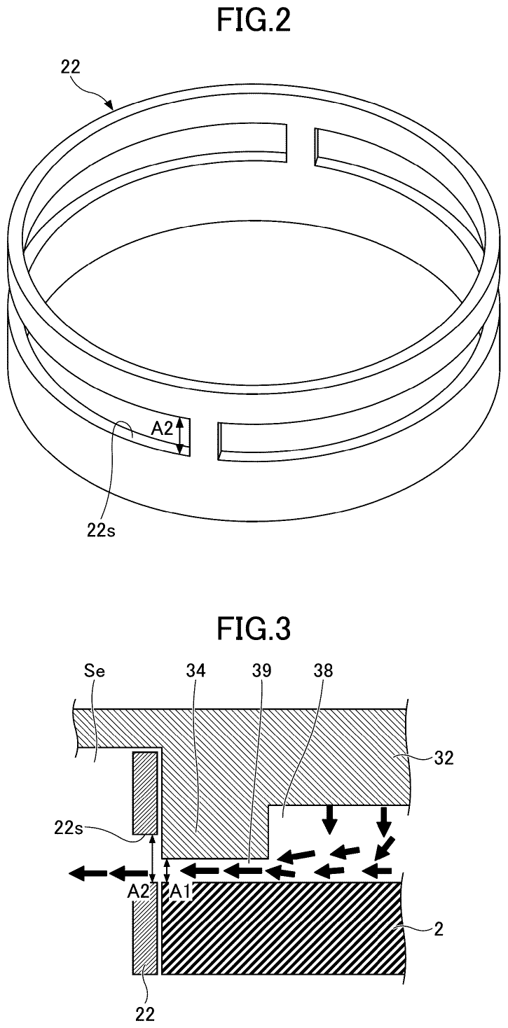

A substrate processing device 100 according to an embodiment of the present disclosure will be described below with reference to FIG. 1 and FIG. 2. FIG. 1 is a cross-sectional view showing the substrate processing device 100 according to an embodiment of the present disclosure. FIG. 2 is a perspective view showing an example of a flow rectifying member 22.

The substrate processing device 100 includes a processing container 1, a stage 2, a shower head 3, an exhaust part 4, a gas supply part 5, an RF power supply part 8, and a control circuit 9.

The processing container 1 is substantially cylindrical in shape. The processing container 1 is made of metal such as aluminum. The processing container 1 contains a substrate W inside. The substrate W is, for example, a semiconductor wafer. In one side wall of the processing container 1, an inlet/outlet 11 is formed so that the substrate W can be loaded in and unloaded from the processing container 1. The inlet/outlet 11 is opened and closed by a gate valve 12. An exhaust duct 13, which is annular in shape and has a rectangular cross section, is provided over the main body of the processing container 1. An exhaust opening 13p is formed in an outer wall of the exhaust duct 13. In this example, there is one exhaust opening 13p. On an upper surface of the exhaust duct 13, a top wall 14 is placed so as to close the upper opening of the processing container 1 via insulating members 16. Sealing members 15 provide an airtight seal between the exhaust duct 13 and the insulating members 16. The sealing members 15 may be, for example, O-rings.

The stage 2 supports the substrate W horizontally in the processing container 1. The stage 2 is shaped like a disk. The outer diameter of the stage 2 is larger than, for example, the outer diameter of the substrate W. The stage 2 is made of a ceramic material such as AlN, a metallic material such as aluminum or a nickel alloy, etc. A heater 21 is provided inside the stage 2. The heater 21 produces heat when power is supplied from a heater power source (not shown). The heater 21 heats the substrate W by producing heat. A thermocouple (not shown) is provided near an upper surface of the stage 2. The output of the heater 21 is controlled by, for example, temperature signals from the thermocouple, so that the temperature of the substrate W is adjusted to a predetermined temperature.

A support member 23 is provided in a bottom surface of the stage 2. The support member 23 supports the stage 2. The support member 23 extends downward from the center of the bottom surface of the stage 2, through a hole part formed in a bottom wall of the processing container 1. The lower edge of the support member 23 is connected to a height-adjusting mechanism 24. The height-adjusting mechanism 24 adjusts the width of the gap between the stage 2 and the shower plate 32 by allowing the stage 2 to move upward and downward via the support member 23. The height-adjusting mechanism 24 is an example of a gap adjusting part. Underneath the processing container 1, a guard part 25 is attached to the support member 23. Bellows 26 are provided between a bottom surface of the processing container 1 and the guard part 25. The bellows 26 separate the atmosphere inside the processing container 1 from the outside air, and expand and contract as the stage 2 moves upward and downward.

Three support pins 27 are provided (only two are shown in FIG. 1) near the bottom surface of the processing container 1 such that they protrude upward from a height-adjusting plate 27a. Each support pin 27, controlled by a height-adjusting mechanism 28 positioned below the processing container 1, moves upward and downward via the height-adjusting plate 27a. The support pins 27 are inserted into respective through-holes 2a formed in the stage 2, allowing them to protrude and retract relative to the upper surface of the stage 2. By moving the support pins 27 upward and downward, the substrate W is transferred between a transport device (not shown) and the stage 2.

A cover member 29 is securely attached to the stage 2. The cover member 29 and the stage 2 move upward and downward together. The cover member 29 covers the bottom and side surfaces of the stage 2. The cover member 29 and the exhaust duct 13 form a diffusion space Se. The cover member 29 is made of ceramics such as alumina. The diffusion space Se is provided near a processing space 38, which will be described later. The processing space 38 serves to diffuse gas flowing out from the processing space 38.

The shower head 3 supplies the gas into the processing container 1 in a shower-like manner (that is, in a sprinkling or scattered distribution). The shower head 3 is positioned to face the stage 2. The shower head 3 is made of metal. The shower head 3 and the stage 2 have substantially the same diameter. The shower head 3 has a main body part 31 and a shower plate 32. The main body part 31 is securely attached to the top wall 14 of the processing container 1. The shower plate 32 is connected with the main body part 31 via the lower portion of the main body part 31. The shower plate 32 is an example of an upper member. A gas diffusion space 33 is formed between the main body part 31 and the shower plate 32. A gas injection hole 36 that penetrates the center of the top wall 14 and the main body part 31 is provided in the gas diffusion space 33. Annular protruding parts 34 that protrude downward are formed in peripheral parts of the shower plate 32. A gas discharging hole 35 is formed in the flat part located inward of the annular protruding parts 34. When the stage 2 is in the processing position, the processing space 38 is formed between the stage 2 and the shower plate 32, and an annular gap 39 is formed when the upper surface of the stage 2 and the annular protruding part 34 move closer to each other. The processing space 38 communicates with the diffusion space Se via the annular gap 39. The height-adjusting mechanism 24 moves the stage 2 upward and downward, thus adjusting the width A1 of the annular gap 39.

A flow rectifying member 22 is positioned so as to surround the processing space 38. The flow rectifying member 22 has a cylindrical shape. The flow rectifying member 22 is positioned so as to cover the side surfaces of the stage 2 and the shower plate 32. The flow rectifying member 22 is positioned nearer to the annular gap 39 than it is to the exhaust opening 13p. This enables the volume of the diffusion space Se to be increased, reducing the likelihood of obstruction of gas flow toward the exhaust opening 13p. The flow rectifying member 22 is supported by the cover member 29. The flow rectifying member 22 moves upward and downward together with the cover member 29 and the stage 2. The flow rectifying member 22 has a slits 22. The slit 22s is formed along the circumference of the flow rectifying member 22. The slit 22s may be divided into multiple slits (two in FIG. 2) in the circumferential direction of the flow rectifying member 22. At least a portion of the gas flowing from the processing space 38 through the annular gap 39 passes through the slit 22s and guided to the diffusion space Se. The height A2 of the slit 22s may be greater than the minimum width A1 of the annular gap 39 when the substrate W is processed in the processing space 38. The height A2 of the slit 22s may be smaller than the maximum width A1 of the annular gap 39 when the substrate W is processed in the processing space 38. The slit 22s is an example of an opening.

The exhaust part 4 evacuates the inside of the processing container 1. The exhaust part 4 includes an exhaust pipe 41 and an exhaust mechanism 42. The exhaust pipe 41 is connected to the exhaust opening 13p. The exhaust mechanism 42 includes: a vacuum pump connected with the exhaust pipe 41; and a pressure control valve. While the substrate W is processed, the gas inside the processing space 38 passes through the annular gap 39 and reaches the diffusion space Se. The exhaust mechanism 42 then exhausts the gas from the exhaust opening 13p, through the exhaust pipe 41.

The gas supply part 5 supplies various gases to the shower head 3. The gas supply part 5 includes a gas source 51 and a gas line 52. The gas source 51 includes a source that supplies various gases, a mass-flow controller, and a valve. The various gases are injected from the gas source 51, through the gas line 52 and the gas injection hole 36, into the gas diffusion space 33. The gases include, for example, a film forming gas, an etching gas, a purge gas, etc.

The substrate processing device 100 is a capacitively-coupled plasma device, with the stage 2 functioning as a lower electrode and the shower head 3 functioning as an upper electrode. The stage 2 is grounded. The shower head 3 is connected to an RF power supply part 8.

The RF power supply part 8 supplies high-frequency power (hereinafter also referred to as “RF power”) to the shower head 3. The RF power supply part 8 includes an RF power source 81, a matching device 82, and a power feed line 83. The RF power source 81 is a power source that generates RF power. The RF power has a frequency that is suitable to generate plasma. The RF power frequency ranges, for example, from the low-frequency 450 kHz band, to the microwave 2.45 GHz band. The RF power source 81 is connected to the main body part 31 via the matching device 82 and the power feed line 83. The matching device 82 includes a circuit for allowing the load impedance to match the internal impedance of the RF power source 81. The RF power supply part 8 may be structured to supply RF power to the stage 2.

The control circuit 9 is an electronic circuit such as a central processing unit (CPU), a field-programmable gate array (FPGA), an application-specific integrated circuit (ASIC), etc. The control circuit 9 performs various control operations described herein by executing instruction codes stored in a memory or by providing a circuit structure designed for a specific application.

### (Control Method)

Referring to FIG. 3 to FIG. 6, a method of controlling the substrate processing device 100 according to an embodiment of the present disclosure will be explained. FIG. 3 to FIG. 6 are diagrams for explaining a method of controlling the substrate processing device 100 according to an embodiment of the present disclosure. In FIG. 3 to FIG. 6, the arrows indicate the gas flow.

The method of controlling the substrate processing device 100 may include allowing the height-adjusting mechanism 24 to perform a first adjustment to adjust the width A1 of the annular gap 39 such that the width A1 is the same as or smaller than the height A2 of the slit 22s. The first adjustment may include allowing the height-adjusting mechanism 24 to move the stage 2 to a first position.

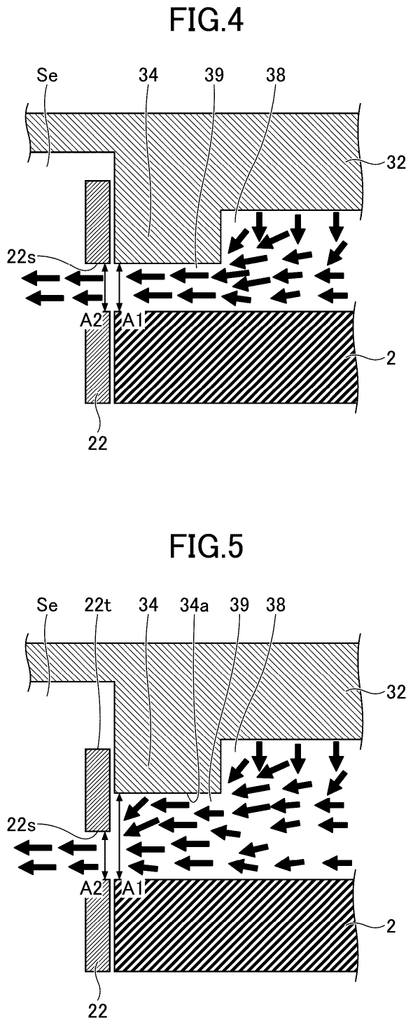

The first position is where the width A1 of the annular gap 39 is smaller than the height A2 of the slit 22 (A1<A2), as shown in FIG. 3, or where the width A1 of the annular gap 39 is the same as the height A2 of the slit 22s (A1=A2), as shown in FIG. 4. When the stage 2 is in the first position, gas is supplied from the shower plate 32 to the processing space 38, passes through the annular gap 39, and is discharged into the diffusion space Se through the slit 22s. Because the width A1 of the annular gap 39 is the same as or smaller than the height A2 of the slit 22s, the flow rectifying member 22 does not obstruct the flow of gas. It then follows that the conductance in the space between the processing space 38 and the diffusion space Se is determined by the width A1 of the annular gap 39, and the peripheral part of the stage 2 is where the conductance is predominant. As a result of this, although there is only one exhaust opening 13p, the gas can be exhausted evenly from around the processing space 38. When the stage 2 is in the first position, the width A1 of the annular gap 39 is, for example, between 0.5 mm and 1.0 mm, inclusive. This facilitates even exhaustion of gas from around the processing space 38.

The method of controlling the substrate processing device 100 may include allowing the height-adjusting mechanism 24 to perform a second adjustment to adjust the width A1 of the annular gap 39 such that the width A1 of the annular gap 39 is larger than the height A2 of the slit 22s and the lower edge 34a of the annular protruding part 34 is positioned lower than the upper edge 22t of the flow rectifying member 22. The second adjustment may include allowing the height-adjusting mechanism 24 to move the stage 2 to a second position.

As shown in FIG. 5, the second position is where the width A1 of the annular gap 39 is larger than the height A2 of the slit 22s (A1>A2), and where the lower edge 34a of the annular protruding part 34 is positioned lower than the upper edge 22t of the flow rectifying member 22. When the stage 2 is in the second position, the gas is supplied from the shower plate 32 to the processing space 38, passes through the annular gap 39, and is discharged into the diffusion space Se through the slit 22s. Because the width A1 of the annular gap 39 is larger than the height A2 of the slit 22s, the conductance in the space between the processing space 38 and the diffusion space Se is determined by the height A2 of the slit 22s, and the peripheral part of the stage 2 is where the conductance is predominant. Despite the fact that there is only one exhaust opening 13p, this facilitates even exhaustion of gas from around the processing space 38, regardless of the width A1 of the annular gap 39. When the stage 2 is in the second position, the width A1 of the annular gap 39 is, for example, between 1.0 mm and 5.0 mm, exclusive.

The method of controlling the substrate processing device 100 may include allowing the height-adjusting mechanism 24 to perform a third adjustment to adjust the width A1 of the annular gap 39 such that the lower edge 34a of the annular protruding part 34 is positioned higher than the upper edge 22t of the flow rectifying member 22. The third adjustment may include allowing the height-adjusting mechanism 24 to move the stage 2 to a third position.

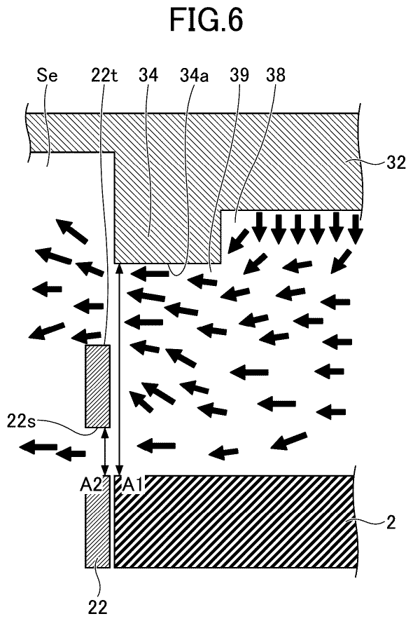

As shown in FIG. 6, the third position is where the lower edge 34a of the annular protruding part 34 is positioned higher than the upper edge 22t of the flow rectifying member 22. When the stage 2 is in the third position, the gas is supplied from the shower plate 32 to the processing space 38, passes through the annular gap 39, and is discharged into the diffusion space Se, through the slit 22s, passing above the flow rectifying member 22. Consequently, when, for example, a large quantity of gas is to be supplied to the processing space 38 from the shower plate 32, the gas can be discharged from the processing space 38 to the diffusion space Se in an efficient way. When the stage 2 is in the third position, the width A1 of the annular gap 39 is, for example, 5.0 mm or more.

The height-adjusting mechanism 24 moves the stage 2 to the first position or to the second position when, for example, the substrate W is processed in the processing space 38. This makes possible even exhaustion of gas from around the processing space 38 when the substrate W is processed, thus leading to improved uniformity in the substrate W's processing.

The height-adjusting mechanism 24 moves the stage 2 to the third position when, for example, purging the processing space 38. In this case, the processing space 38 can be purged by supplying a large quantity of purge gas to the processing space 38, thereby shortening the time required for the purging.

The presently disclosed embodiment should be considered in all respects as illustrative and not restrictive. The above-described embodiment may be omitted, substituted, or modified in a variety of ways without departing from the spirit and scope of the accompanying claims.

Although the above embodiment has been described assuming a case in which one exhaust opening 13p is formed in the outer wall of the exhaust duct 13, the present disclosure is by no means limited to this, and, for example, two or more exhaust openings 13p may be formed along the circumference of the exhaust duct 13.

Although the above embodiment has been described assuming a case in which the slit 22s serves as an opening, the present disclosure is by no means limited to this, and for example, multiple punched holes may be formed along the circumference of the flow rectifying member 22 and serve as openings.

Although the above embodiment has been described assuming a case in which the shower plate 32 serves as an upper member, the present disclosure is by no means limited to this, and, for example, any member that provides a processing space 38 between itself and the stage 2 may serve as an upper member.

Although the above embodiment has been described assuming a case in which the width A1 of the annular gap 39 is adjusted by moving the stage 2 upward and downward, the present disclosure is by no means limited to this, and, for example, the shower plate 32 may be structured to move upward and downward, and the width A1 of the annular gap 39 may be adjusted by the upward and downward movement of the shower plate 32. Alternatively, for example, the stage 2 and the shower plate 32 may be both structured to move upward and downward, and the width A1 of the annular gap 39 may be adjusted by moving both the stage 2 and the shower plate 32 upward and downward.

What is claimed is:

1. A substrate processing device comprising:
a processing container;
a stage configured to support a substrate in the processing container;
an upper member that is positioned to face the stage so as to form a processing space therebetween;
a gap adjusting part configured to adjust a width of a gap between the stage and the upper member; and
a flow rectifying member that is positioned to surround the processing space,
wherein the flow rectifying member has an opening through which at least a portion of gas flowing out from the processing space passes.

2. The substrate processing device according to claim 1, wherein the gap adjusting part is further configured to perform:
a first adjustment to adjust the width of the gap such that the width of the gap is same as or smaller than a height of the opening;
a second adjustment to adjust the width of the gap such that the width of the gap is larger than the height of the opening and a lower edge of the upper member is positioned lower than an upper edge of the flow rectifying member; or
a third adjustment to adjust the width of the gap such that the lower edge of the upper member is positioned higher than the upper edge of the flow rectifying member.

3. The substrate processing device according to claim 2, wherein the gap adjusting part is further configured to perform the first adjustment or the second adjustment when the substrate is processed in the processing space.

4. The substrate processing device according to claim 2, wherein the gap adjusting part is configured to perform the third adjustment when the processing space is purged.

5. The substrate processing device according to claim 1, wherein a height of the opening is larger than a minimum value of the width of the gap used when the substrate is processed in the processing space.

6. The substrate processing device according to claim 1, wherein a height of the opening is smaller than a maximum value of the width of the gap used when the substrate is processed in the processing space.

7. The substrate processing device according to claim 1, wherein the gap adjusting part is further configured to adjust the width of the gap by allowing the stage to move upward and downward.

8. The substrate processing device according to claim 7, wherein the flow rectifying member is configured to move upward and downward together with the stage.

9. The substrate processing device according to claim 1, wherein the gap adjusting part is further configured to adjust the width of the gap by allowing the upper member to move upward and downward.

10. The substrate processing device according to claim 1, wherein the upper member is a shower plate that is configured to supply the gas to the processing space in a shower-like manner.

11. The substrate processing device according to claim 1, further comprising an exhaust duct that is positioned near the processing space to form a diffusion space, the diffusion space serving to diffuse the gas flowing out from the processing space.

12. A method of controlling a substrate processing device,
the substrate processing device comprising:
a processing container;
a stage configured to support a substrate in the processing container;
an upper member that is positioned to face the stage so as to form a processing space therebetween;
a gap adjusting part configured to adjust a width of a gap between the stage and the upper member; and
a flow rectifying member that is positioned to surround the processing space,
wherein the flow rectifying member has an opening through which at least a portion of gas flowing out from the processing space passes, and
the method comprising:
adjusting, by the gap adjusting part, the width of the gap such that the width of the gap is same as or smaller than a height of the opening;
adjusting, by the gap adjusting part, the width of the gap such that the width of the gap is larger than the height of the opening and a lower edge of the upper member is positioned lower than an upper edge of the flow rectifying member; or
adjusting, by the gap adjusting part, the width of the gap such that the lower edge of the upper member is positioned higher than the upper edge of the flow rectifying member.
